(19) United States
(12) Patent Application Publication
(10) Pub. No.: US 2009/0121798 A1
(43) Pub. Date: May 14, 2009

(54) HIGH POWER MICROWAVE WASTE MANAGEMENT

(76) Inventor: Melvin Leroy Levinson, Edison, NJ (US)

Correspondence Address: Melvin Levinson, 8 Stratford Circle, Edison, NJ, 08820, US

(21) Appl. No.: 11/837,384

(22) Filed: Aug. 10, 2007

(51) Int. Cl. H03B 9/00

(52) U.S. Cl. 331/71

(57) ABSTRACT

A variable capacitor power supply for a high-power, industrial magnetron is powered directly from a conventional, public-service, 4,160 volt and higher power line. The magnetron's output is removably attached to a tractor trailers or train boxcar fabricated as a microwave work chambers. Microwave work chambers are configured to dry waste, burn dried waste, enhance chemical processes, fix free nitrogen, burn waste metal, reclaim component metals from mixed waste metal, and for gasification, pyrolysis, and plasma waste disposal. Alternately, the microwave power supply is removably connected to an underground cave, configured as a microwave oven chamber, to microwave waste therein. The microwave power supply is located in the basement of a high rise building designed to convert the high rise building waste into heat and electricity.

### BACKGROUND OF THE INVENTION

1. Field of the Invention

The invention concerns industrial waste management methods that include drying waste, burning dried waste, enhancing chemical processes, fixing free nitrogen, burning waste metal, reclaiming component metals from mixed waste metal, and gasification, pyrolysis, and plasma waste disposal. The high-power, microwave energy apparatus is designed to replace the gas and electric apparatus and the methods presently employed in industrial drying, chemical and waste management facilities.

2. Discussion of Background

Waste management is the collection, transport, processing (waste treatment), recycling or disposal of waste materials in an effort to reduce their effect on human health or local aesthetics or amenity. A sub focus in recent decades has been to reduce waste materials' effect on the natural world and the environment and to recover resources from them. This invention concerns solid, liquid and gaseous waste management and their different requirements, procedures and fields of expertise. For example:

Landfill: Older or poorly managed landfills can create a number of adverse environmental impacts, including wind-blown litter, attraction of vermin and pollutants such as leachate, which can leach into and pollute groundwater and rivers. Another product of landfills containing harmful wastes is landfill gas, mostly composed of methane and carbon dioxide, which is produced as the waste breaks down anaerobically.

Characteristics of a modern landfill include methods to contain leachate, such as lining clay or plastic liners. Disposed waste should be compacted and covered to prevent attracting mice and rats and preventing wind-blown litter. Many landfills also have a landfill gas extraction system installed after closure to extract the gas generated by the decomposing waste materials. This gas is often burnt in a gas engine to generate electricity. Even flaring the gas off is a better environmental outcome than allowing it to escape to the atmosphere, as this consumes the methane, which is a far stronger greenhouse gas than carbon dioxide. Some of the gas can be tapped for use as a fuel.

Incineration: Incineration is the process of destroying waste material by burning it. Incineration is often alternatively named “Energy-from-waste” or “waste-to-energy”; this is misleading as there are other ways of recovering energy from waste that do not involve directly burning it (e.g., anaerobic digestion, pyrolysis & gasification).

Incineration is carried out on a large scale by industry. It is recognized as a practical method of disposing of hazardous waste materials, such as medical waste. Many entities now refer to disposal of waste by exposure to high temperatures as “thermal treatment” (however this also includes gasification and pyrolysis). This concept encompasses recovery of metals and energy from municipal solid waste as well as safe disposal of the remaining ash and reduction of the volume of waste.

Though classic incineration is still widely used in many areas, especially developing countries, incineration as a waste management tool is becoming controversial for several reasons. First, it may be a poor use of many waste materials because it destroys not only the raw material, but also all of the energy, water, and other natural resources used to produce it. Some energy can be reclaimed as electricity by using the combustion to create steam to drive an electrical generator, but even the best incinerator can only recover a fraction of the caloric value of fuel materials. Second, incineration of municipal solid wastes does produce significant amounts of dioxin and furan emissions to the atmosphere. Dioxins and furans are considered by many to be serious health hazards. Incineration also produces large amounts of ash requiring safe disposal so as not to contaminate underground aquifers. Until recently, safe disposal of incinerator ash was a major problem. In the mid-1990s, experiments in France and Germany used electric plasma torches to melt incinerator ash into inert glassy pebbles, valuable in concrete production. Incinerator ash has also been chemically separated into lye and other useful chemicals. This process, plasma arc waste disposal, is now operated commercially, and is used to convert existing waste and landfill into power generating gas and construction rubble. An incineration technique that avoids ash disposal problems is the incorporation of the ash in portland cement furnaces, with savings of fuel, a double benefit.

Pyrolysis & Gasification: Pyrolysis and gasification are two related forms of thermal treatment where materials are heated with high temperatures and limited oxygen. The process typically occurs in a sealed vessel under high pressure. Converting material to energy this way is more efficient than direct incineration, with more energy able to be recovered and used. Pyrolysis of solid waste converts the material into solid, liquid and gas products. The liquid oil and gas can be burnt to produce energy or refined into other products. The solid residue (char) can be further refined into products such as activated carbon. Gasification is used to convert organic materials directly into a synthetic gas (syngas) composed of carbon monoxide and hydrogen. The gas is then burnt to produce electricity and steam. Gasification is used in biomass power stations to produce renewable energy and heat.

Plasma Gasification is the gasification of matter in an oxygen-starved environment to decompose waste material into its basic molecular structure. Plasma gasification does not combust waste as incinerators do. It converts organic waste into a fuel gas that still contains all the chemical and heat energy from the waste. It converts inorganic waste into an inert vitrified glass. Plasma is considered as a 4th state of matter, the other three being gas, liquid, and solid. Electricity is fed to a torch, which has two electrodes, creating an arc. Inert gas is passed through the arc, heating the process gas to internal temperatures as high as 13,000° C. (25,000° F.). The temperature a meter from the torch can be as high as ˜4000° C. (˜8,000° F.). Because of these high temperatures the waste is completely destroyed and broken down into its basic elemental components. There are no tars or furans. At these high temperatures all metals become molten and flow out the bottom of the reactor. Inorganics such as silica, soil, concrete, glass, and gravel are vitrified into glass and flow out the bottom of the reactor. There is no ash remaining to go back to a landfill. The plasma reactor does not discriminate between types of waste. It can process any type of waste. The only variable is the amount of energy that it takes to destroy the waste. Consequently, no sorting of waste is necessary and any type of waste, other than nuclear waste, can be processed. The reactors are large and operate at a slightly negative pressure, meaning that the feed system is simplified because the gas does not want to escape. The gas has to be pulled from the reactor by the suction of the compressor. Each reactor can process 20 tons per hour compared to 3 tons per hour for typical gasifiers. Because of the size and negative pressure, the feed system can handle bundles of material up to 1 metre in size. This means that whole drums or bags of waste can be fed directly into the reactor making the system ideal for large scale production. The gas coming out of a plasma gasifier is lower in trace contaminants than with any kind of incinerator or other gasifier. Because the process starts with lower emissions out of the reactor, it is able to achieve significantly lower stack emissions. The gasifier doesn't care about the amount of moisture in the waste. The moisture consumes energy to vaporize and can impact the capacity and economics; however, it will not affect the process. Gas from the plasma reactor can be burned to produce electricity or can be synthesized into ethanol to contribute to automotive fuel.

Mechanical Biological Treatment is a technology category for combinations of mechanical sorting and biological treatment of the organic fraction of municipal waste. The “mechanical” element is usually a bulk handling mechanical sorting stage. This either removes recyclable elements from a mixed waste stream (such as metals, plastics and glass) or processes. The “biological” element refers to either anaerobic digestion or composting. Anaerobic digestion breaks down the biodegradable component of the waste to produce biogas and soil conditioner. The biogas can be used to generate renewable energy. More advanced processes such as the ArrowBio Process enable high rates of gas and green energy. This is facilitated by processing the waste in water.

It is an object of this invention to augment or replace gas and electric furnaces presently employed in the aforementioned waste disposal processes with a variable-output, high-power, microwave energy power supply.

It is an object of this invention to teach methods for using a variable-output, high-power, microwave power supply to augment or replace the gas and electric heating apparatus methods presently employed in large scale industrial yeast fermentation, drying, chemical and waste management facilities.

It is an object of this invention to utilize the teaching of my:
a. U.S. Pat. No. 3,469,053 “Microwave Kiln” teaches a microwave oven capable of refractory temperatures;
b. U.S. Pat. No. 3,452,176 “Heating A Moving Conductor By Electromagnetic Wave Irradiation In The Microwave Region” teaches where an electrical conductor (e.g. metal wire, rod, and conduit) is caused to pass through a heated microwave kiln to heat treat said conductor;
c. U.S. Pat. No. 3,539,751 “Insulating Implement For Use In A Microwave Oven” teaches microwave heating an article while said article is inside a “thermos bottle” with an auxiliary microwave heating element present within said “thermos bottle. This patent teaches heat insulating shelves, trays and walls;
d. U.S. Pat. No. 3,569,657 “Methods Of Processing And Transporting Articles” teaches that a microwave heating chamber and a microwave generator can exist independently and need not be immovably or permanently attached. U.S. Pat. No. 3,569,657 teaches that a microwave heating chamber can be a tractor trailer or train boxcar which is removably connected to a microwave generator. Material is loaded into a freight car. It is driven to a microwave generator, microwaved and then delivered to a final destination. This obviates the old art process of 1) loading waste, 2) unloading the waste, 3) loading the unloaded waste into microwave oven chamber, 4) microwave heating the waste, 5) unloading the microwaved waste, and then 6) reloading the microwaved waste back into a freight car for disposal;
e. U.S. Pat. No. 3,585,258 “Methods Of Firing Ceramic Articles Utilizing Microwave Energy” teaches microwaving an article while utilizing microwave heating material to heat the article to a refractory temperature. This patent teaches locating a microwave lossy heating material within an article or submerging an article within a microwave lossy heating material;
f. U.S. Pat. No. 3,732,504 “Power Supply Circuit For A Heating Magnetron” teaches using a variable inductance as a watt-less, variable-power control for a microwave oven;
g. U.S. Pat. No. 3,760,291 “Power Supply For A Heating Magnetron” teaches a power supply circuit for varying the power output of a heating magnetron;
h. U.S. Pat. No. 3,777,099, “Methods Of Heating An Article In A Microwave Oven” teaches heating an article by microwave, electric arc heating;
i. U.S. Pat. No. 3,792,369 “Variable Reactance Controls For Ac Powered Heating Magnetrons” teaches a variable capacitance power supply for a high-power, industrial magnetron. The magnetron power supply is operated without a bulky, expensive, high-power, high-voltage transformer to step down a utility voltage to a factory service voltage and a second high-power, high-voltage transformer to step up the factory service voltage to the high voltage required to power the high-power, industrial magnetron where both high-power transformers are massive, space consuming and both high-power transformers add 7-10% losses to the cost of powering the industrial high-power magnetron;
j. U.S. Pat. No. 3,876,956 “A Regulated Power Supply Circuit For A Heating Magnetron” teaches using a voltage doubler capacitor power supply to power a magnetron;
k. U.S. Pat. No. 4,103,431 “Microwave Drying” teaches apparatus for uniformly drying and bone drying material in a microwave oven; and the teachings of:

Assigned to The United States Department of Energy, Washington, D.C., U.S. Pat. No. 5,843,287 “Method For Recovering Metals From Waste”, by Wicks, et al, teaches a method for recovering metals from metals-containing wastes, and vitrifying the remainder of the wastes for disposal. Metals-containing wastes such as circuit boards, cathode ray tubes, vacuum tubes, transistors and so forth, are broken up and placed in a suitable container. The container is heated by microwaves to a first temperature in the range of approximately 300°-800° C. to combust organic materials in the waste, then heated further to a second temperature in the range of approximately 1,000°-1,550° C. at which temperature glass formers present in the waste will cause it to melt and vitrify. Low-melting-point metals such as tin and aluminum can be recovered after the organics combustion is substantially complete. Metals with higher melting points, such as gold, silver and copper, can be recovered from the solidified product or separated from the waste at their respective melting points. Network former-containing materials can be added at the start of the process to assist vitrification in novel combinations and configurations to reduce the overall volume of waste and convert waste into useful products.

It is an object of this invention to teach an improved microwave power supply designed to reduce the cost and increase the efficiency of existing gas and electric waste disposal processes.

It is an object of this invention to innovate a variable-output, high-power, microwave energy apparatus to augment or replace gas and electric apparatus and methods presently employed in large scale drying, yeast fermentation, chemical and waste management facilities.

It is an object of this invention to teach a high-power, microwave power supply that is removably connected to underground caves or excavations configured as microwave oven chambers to microwave waste therein.

It is an object of this invention to teach a high-power, microwave power supply designed to fit into the basement of a high rise building to burn up waste and to generate electricity from the heat emitted by the burning waste.

It is an object of this invention to teach a microwave waste management power supply designed to dry waste, burn dried waste, enhance chemical processes, fix free nitrogen, burn waste metal, reclaim component metals from mixed waste metal, and for gasification, pyrolysis, and plasma waste disposal.

### SUMMARY OF THE INVENTION

A power supply for a high-power, industrial magnetron is connected directly to a conventional public service 4,160 volt and higher power line. A variable capacitor provides wattless, variable power control to the industrial magnetron. The microwave output of the high-power, industrial magnetron is removably attached to a series of tractor trailers or train boxcars each configured as a microwave work chamber. Individual tractor trailer or train boxcar chambers are designed to enhance 1) drying waste material, 2) burning waste metal, 3) reclaiming component metals from mixed waste metals, 4) gasification, pyrolysis, and plasma waste disposal 5) enhancing chemical processes or 6) fixing free nitrogen. The high-power, microwave power supply is taught removably connected to underground caves or excavations configured as microwave oven chambers to microwave waste therein. The high-power, microwave power supply is taught located in the basement of a high rise building, powered from an underground high-voltage, public utility electric service. The basement microwave power supply is designed to burn up the high rise building's waste and to generate electricity from the heat emitted by the burning waste.

### BRIEF DESCRIPTION OF THE DRAWING

The advantages and benefits resulting from the described high-power microwave power supply will become apparent from the following detailed description by reference to the accompanying drawings in which:

FIG. 1 is a schematic, diagram representation of a variable output, high-voltage, microwave power supply that is removably connected to a microwave chamber located in a tractor trailer or train boxcar.

FIG. 2 is a diagram representation of a tractor trailer or train boxcar dedicated to drying liquid waste, configured as taught in my U.S. Pat. No. 4,103,431 “Microwave Drying”.

FIG. 3 is a diagram representation of a tractor trailer or train boxcar configured to fix free nitrogen.

FIG. 4 is a diagram representation of a tractor trailer or train boxcar with a work chamber 40 configured to follow the teachings of U.S. Pat. No. 5,843,287, “Method For Recovering Metals From Waste”.

FIG. 5 is a diagram representation of a tractor trailer or train boxcar with a work chamber configured to be employed to extract useful by-products from waste by gasification, pyrolysis, heating waste to a plasma, igniting metal waste and reducing metals into metal oxides.

FIG. 6 is a diagram representation of an underground cave configured as a microwave oven chamber designed to receive waste and microwave said waste material for ultimate disposal therein when said cave is removably connected to a high-power, microwave apparatus of the type illustrated in FIG. 1.

FIG. 7 is a diagram representation of a high-power microwave power supply waste disposal room located in basement of high rise residential or office building.

### DETAILED DESCRIPTION OF PREFERRED EMBODIMENTS

My U.S. Pat. No. 3,792,369 “Variable Reactance Controls For Ac Powered Heating Magnetrons” teaches a power supply for a high-power, industrial magnetron in which a variable capacitor provides wattless, variable power control. U.S. Pat. No. 3,792,369 teaches, in industrial, microwave applications, a power supply that operates without the need for a massive, bulky, space-consuming, public-utility, high-power, high-voltage step-down transformer and without the need for a massive, bulky, space-consuming, high-power, high-voltage step-up transformer to power a high-power magnetron. My U.S. Pat. No. 3,792,369 teaches that when a variable capacitance, high-power magnetron power supply is connected between a conventional public service power line, 4,160 volts and higher, and ground. There are substantial cost savings by obviating 1) the 7-10% operating losses inherent in a public utility high-power, high-voltage step-down transformer, 2) the 7-10% operating losses inherent in the presently employed high-power, high-voltage step-up magnetron transformer, 3) the cost of these two massive transformers and 4) their requirement for valuable industrial space.

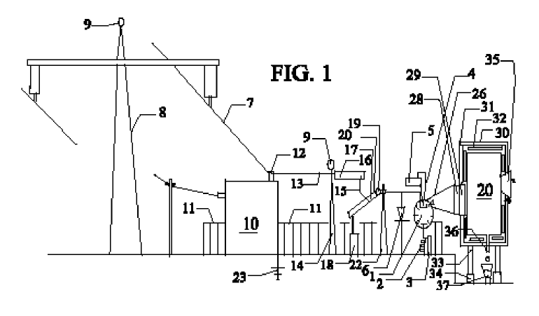

In a preferred embodiment, in FIG. 1, high-power magnetron 1, with an electromagnetic field coil 2 powered by field coil power supply 3, has a filament 4. Magnetron 1's filament 4 is powered by a remotely controlled (not shown) storage battery power supply 5. Electromagnetic field coil 2, powered by field coil power supply 3, connects the anode 24 of magnetron 1 to common ground 23. High voltage diode 6 is connected from the cathode 25 of magnetron 1 to common ground 23.

In FIG. 1, magnetron 1's power supply is powered from high voltage tap 12 on public-utility, high-voltage power-transformer 10 that connects to a high-voltage power-line 7 descending from public-utility, high-voltage tower 8. Lightening arrestor 9 on high voltage tower 8 and lightening arrestor 9 on high voltage tower 14 and other lightening arrestors (not shown) protect the system from lightening strikes. Power line 13 connects high voltage tap 12 to high voltage tower 14. High voltage tower 14 attaches to and supports fixed upper plate 16 of variable capacitor 15.

High voltage tower 22 attaches to and supports remotely controlled mechanism means 18. Mechanism means 18 operates movable lower plate 17 of variable capacitor 15. When variable capacitors 5's lower plate 17 is at its farthest position from variable capacitor 15's fixed upper plate 16 magnetron 1 is turned off. Hinge 19, mounted on high voltage tower 22, and is attached to end 20 of lower plate 17 of variable high voltage capacitor 15. Wire 21 connects high voltage capacitor 15's lower plate 17 to the plate of diode 6 and magnetron 1's cathode 25. In operation, magnetron 1's output feeds a horn antenna 26 that terminates in microwave energy output connector 28.

My U.S. Pat. No. 3,569,657 “Methods Of Processing And Transporting Articles” teaches that a microwave heating chamber and a microwave generator can exist independently and can be removably attached. One microwave generator can be used to microwave material located in a series of tractor trailers, train boxcars and the like configured as microwave heating chambers. In operation, waste material is loaded into a reusable or disposable tractor trailer or train boxcar microwave oven, driven to a microwave generator facility, individually microwaved and then, while cooling, delivered to a dump site. This type operation obviates the need to first load a tractor trailer or train boxcar with waste material, drive it to the microwave generator facility, there unload the tractor trailer or train boxcar and transfer the waste material into a dedicated microwave oven chamber, expose the waste material to microwave energy, unload the microwaved waste from the dedicated microwave oven chamber and load the microwaved waste back into a tractor trailer or train boxcar for subsequent delivery to a dump site.

In FIG. 1 tractor trailer or train boxcar 30 is configured to be impervious to microwave energy and is lined with microwave permeable heat insulating material 31. Preferably tractor trailer or train boxcar 30's heating chamber 20 is configured following the teachings of my U.S. Pat. No. 3,539,751 “Insulating Implement For Use In A Microwave Oven.” Tractor trailer or train boxcar 20's heating chamber 20 includes heat-insulating structure 32, access door 35, and magnetron load input connector 29. Tractor trailer or train boxcar 30 is equipped with wheels 33 that operate on track or roadway 34. As taught in my U.S. Pat. No. 4,103,431 “Microwave Drying,” tractor trailer or train boxcar's heating chamber includes temperature sensor liquid waste means 36 to channel waste liquids and gas forced out of microwave chamber 20 into waste liquid and gas means 37 for subsequent use or disposal.

FIG. 2 illustrates a side view of tractor trailer or train boxcar 30 with work chamber 20 dedicated to drying liquid waste, as taught in my U.S. Pat. No. 4,103,431 “Microwave Drying.” If, after drying, the microwaved dried material in chamber 20 is further microwaved and burned, steam is generated in apparatus 53 and it is employed to power an electric generator (not shown).

FIG. 3 illustrates tractor trailer or train boxcar 39 with work chamber 54 dedicated to fixing free nitrogen. Work chamber 54 is filled with ferrite chips. Forced air apparatus 55 is configured to blow air (nitrogen and oxygen) through work chamber 54. When exposed to microwave energy, the ferrite chips arc and turn red hot. Nitrogen in the air forced through the red hot arcing ferrite chips in work chamber 56 is fixed and exits tractor trailer or train boxcar 39 through fixed nitrogen outlet 53 for conventional processing. Microwave arcing of ferrite chips is taught in my U.S. Pat. No. 3,469,053 “Microwave Kiln”; U.S. Pat. No. 3,452,176 “Heating A Moving Conductor By Electromagnetic Wave Irradiation In The Microwave Region”; and U.S. Pat. No. 3,585,258 “Methods Of Firing Ceramic Articles Utilizing Microwave Energy.”

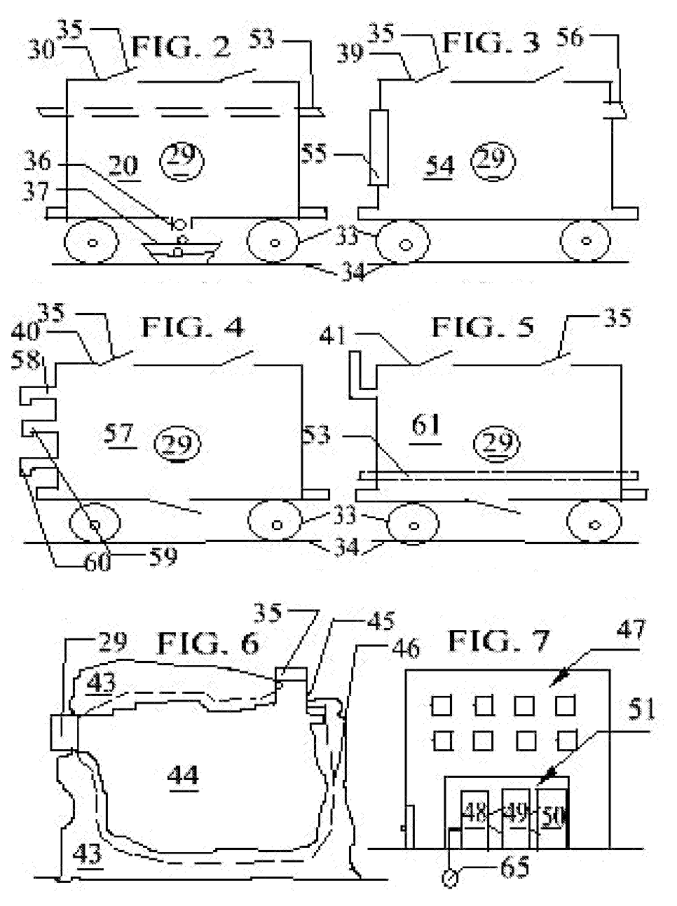

FIG. 4 illustrates a tractor trailer or train boxcar 40 with a work chamber 57 configured to follow the teachings of U.S. Pat. No. 5,843,287 “Method For Recovering Metals From Waste.” Mixed metal waste enters work chamber 57 through access door 35. The mixed metal waste is exposed to microwave energy in work chamber 57 and the individual recovered metals exit work chamber through recovered metal outlets 58, 59 and 60.

FIG. 5 illustrates tractor trailer or train boxcar 41 with heat insulated microwave work chamber 61 configured to extract useful by-products from waste by gasification, pyrolysis, and heating waste to a plasma. Alternately, heat insulated microwave work chamber 61 in tractor trailer or train boxcar 41 can be configured to, when exposed to microwaves, ignite metal waste until it is thoroughly burned and reduced to metal oxides. Chamber 61 can be equipped with apparatus 53 designed to boil water when heated by the burning waste metal. Steam generated in apparatus 53 can be employed to power an electric steam generator (not shown). Note, ignited a match can be employed to ignite wood or coal, but ignited burning wood or coal is not hot enough to ignite metal. In contrast, exposed to microwave energy metal ignites and burns. Microwaves can initiate thermite reactions. Once ignited by microwave energy, in the presence air, metal waste burns fiercely and the immense heat evolved can be employed to power a steam generator.

FIG. 6 illustrates microwaving waste material in cave chamber 44 in dry ground 43. In operation, a microwave generator apparatus (as shown in FIG. 1) is removably attached to a mating, magnetron connector 29, attached to the entrance of cave chamber 44. The man made waste material in cave chamber 44 is microwaved and then the microwave generator apparatus is moved to another cave. After microwaving, the waste material is reduced in volume and is free of contamination. After microwaving, cave chamber 44, now containing uncontaminated microwaved waste material is sealed and becomes an uncontaminated land fill. An optional access structure 45 to cave chamber 44 can be employed to, after the first microwaving, add additional waste and then the additional waste is microwaved until cave chamber 44 is filled with uncontaminated microwaved waste material. If necessary, metal screening 46 is buried in ground 43 surrounding cave chamber 44 to contain microwave energy in cave chamber 44.

FIG. 7 illustrates another embodiment of the invention where high-power, microwave power supply 48 is located in a basement heating room 51 of high-rise residential or office building 47. High-power, microwave power supply 48, configured as in FIG. 1, is powered and varied except that its high-power, electric utility source is an underground high-voltage utility line 65. High-power microwave power supply 48 supplies microwave energy to waste disposal microwave oven chamber 49 to first dry and then burn waste material. Microwave oven chamber 49 is designed to receive building 47's waste and, therein, expose the waste to the microwave energy from microwave power supply 48. Equipment 50 converts heat generated in waste disposal microwave oven chamber 49 into electricity to power and when necessary supply heat to high rise building 47. Water expelled from the drying waste is flushed down a sewer.

In FIG. 1, in operation, following the teachings of my U.S. Pat. No. 3,792,369 “Variable Reactance Controls For AC Powered Heating Magnetrons,” the capacity of variable capacitor 15 is chosen so that the high-voltage present, on electric-utility transformer tap 12, applied across the circuit, that includes capacitor 15 at its maximum capacity in series with the parallel combination of magnetron 1 and high voltage diode 6 and ground, will result in a flow of current through magnetron 1 below magnetron 1's maximum allowed current. Thereupon, in operation, lowering the capacitance of variable capacitor 15 will lower the output of magnetron 1. Magnetron 1's electromagnet 2 is powered by electromagnet's power supply 3. Magnetron 1 is turned on and off when capacitor 15 is at its smallest capacitance and magnetron 1 is emitting its lowest output of microwave energy. At off, to preclude magnetron 1 from emitting microwave energy, some may turn off magnetron 1's electromagnet power supply 3 and thereby turn magnetron 1 into a simple diode tube that can not emit microwave energy. At a given frequency the size of a magnetron is fixed and its power output is the result of its plate voltage and the power of its electromagnet.

Filament supply 5 is exposed to the same high voltage as magnetron 1's cathode and would normally require an expensive, high-voltage, space-consuming, magnetron filament transformer. In FIG. 1, to obviate the need for an expensive, high-voltage, space-consuming, magnetron filament transformer, the filament of magnetron 1 is powered from storage-battery, filament power supply 5 exposed to the same high voltage as the filament-cathode of magnetron 1. Storage-battery filament power supply 5 is configured to be remotely controlled by the same operator (not shown) of mechanism 18 that varies the capacity of variable capacitor 15. Initially when switched on, storage-battery, filament supply 5 is designed to supply the filament voltage magnetron 1 requires to initiate operation and during operation storage-battery filament supply 5's voltage is lowered if electron back bombardment of cathode 25 warrants said lowering.

FIG. 1 illustrates, as part of its normal fenced in substation, a megawatt magnetron power supply owned and operated by a public utility. The illustrated magnetron power supply does not require placement in a public utility substation. It is easily transported and is useful in rural farm communities here or in foreign countries. Said transported high-power, magnetron power supply, becomes operational by simply connecting it to any 4,160 volt or higher conventional utility line and to a ground. It can be connected to 50 cycle or 60 cycle lines. Two or three magnetron power supplies can be powered simultaneously from each leg of a two phase or three phase electric utility line. Simultaneously operating three magnetron power supplies, each supplied by a different leg of the three phase line and designed to heat the same load can result in a more uniform heating of the load. It is expected that, if said magnetron power supply was operated in a heavily populated country as India, the operators of the power supply could pay, for example, a hundred million or more poor people to regularly bring in buckets of human and animal waste to be microwaved and turned into needed water and electricity.

It should be appreciated that the heat energy generated from microwaving waste has two parts 1) the heat evolved by the microwaving waste, per se, and 2) the microwave energy that turned into heat to ignite and “supercombust” (infra) the waste. When microwaving waste is employed to power an electric generator, the microwave energy is not lost it combines with the heat output of the burning waste to power the electric generator. In effect much of the microwaving energy expended burning waste is recycled back into the electric power source that powers the microwave power supply.

Because said magnetron power supply is designed to heat large loads, waveguides, circulators, field stirrers and the like are not required. Microwave arcing, spot, end and selected heating of solid waste hasten the ignition of waste material. Microwave arcing, spot, end and selected heating are not a factor when microwaving liquid waste.

To permit a public utility electric service to accommodate the turning off and on of a megawatt microwave power supply, in operation, the magnetron's high wattage output is turned on at low and slowly adjusted to maximum and, when it is time to turn off the magnetron power apparatus the variable capacitor is slowly adjusted to minimum microwave output. Note, power expended in the variable capacitor is wattless power and its capacitance adds capacitance to public utility power lines and usefully balances out some of the undesirable high inductive reactance normally present on public utility power lines.

It is expected that operators of mechanical biological treatment facilities, which rely on anaerobic digestion to break down the biodegradable component of waste to produce biogas and soil conditioner, will rely on the variable power aspect of the variable-output, high-power, microwave energy apparatus taught herein. Operators of biological treatment facilities will heat and hold a biomass at a temperature that is just below the kill temperature of the active organisms in the biomass to speed the active organisms' digestion. While waste disposal has been emphasized, the variable-output, high-power, microwave energy apparatus taught herein is useful in commercial industrial processes. For example, in the bread industry to proof bread and in the beer industry to ferment malt. The variable-output, high-power, microwave energy apparatus taught herein is useful to speed yeast's fermentation by heating and holding yeast mixtures at a temperature that is just below the kill temperature of the yeast. Microwave energy is more useful than gas and electric heating to heat and hold at a given temperature a large batch of fermenting yeast. This is because microwave energy heats in depth three dimensionally. In contrast, gas and electric heating heats a large batch of fermenting yeast from exposed, heated surfaces. Unlike microwave heating, when high-power gas or electric heat is employed to evenly heat and hold at a selected temperature a large batch of fermenting yeast, the yeast, directly in contact with gas and electric heated surfaces, are killed.

The variable-output, high-power, microwave energy apparatus taught herein is useful to increase the heat output of a burning fuel. A burning fuel exposed to microwave energy “supercombusts.” “Supercombustion” is a term I coined, in 1965, to describe the operation of my U.S. Pat. No. 3,469,053, a “Microwave Kiln.” When I microwaved pure charcoal, it ignited and unexpectedly burned fiercely. I microwaved better fuels as wood, coal and the like until they ignited and not only burned fiercely they would “supercombust.” Continued application of microwave energy resulted in plasma discharges that looked and sounded like lightening flashes. “Supercombusting” fuel burns up and is consumed more rapidly than a burning fuel not exposed to microwave energy. When “supercombustion” is used to boil water to power an electric generator, the high burning temperature and high caloric output of “supercombusting” fuel results in cost savings. Additionally, the microwave energy that turned into the heat energy required to “supercombust” ads to the heat energy expended by the burning fuel used to boil water to power an electric generator and, in effect, microwave energy is recycled.

Although this invention has been described with a certain degree of particularity, it is understood that the present disclosure has been made by way of example and that numerous changes in details of construction and arrangement of parts may be resorted to without departing from the spirit and scope of the invention.

What is claimed is:

1. A variable-output, magnetron power supply which comprises:
a high-voltage, electric service 4,160 volts and higher connected to a variable capacitor in series with a magnetron and ground,
where at maximum capacity said variable capacitor's size is chosen to limit the current flowing through said magnetron to a value below its maximum allowable plate current, and
where the magnetron's filament voltage is supplied by a remotely operated power supply that operates at the magnetron's filament voltage.

2. Apparatus according to claim 1, where the power output of said magnetron terminates in a coupling that is configured to removably attach to a microwave oven chamber's input coupling.

3. Apparatus according to claim 2, where said microwave chamber is located within a tractor trailer or train boxcar, and
where the microwave chamber has an input coupling that is configured to mate with said removable coupling on the output of said magnetron.

4. Apparatus according to claim 3, where microwave chambers located within a plurality of tractor trailer or train boxcars are configured and selected from a group of chambers designed to fix free nitrogen, to reclaim individual metals from mixed waste metal, reduce metal wastes to their metal oxides, dry wet waste and then burn it, and designed to extract useful by-products from waste by gasification, pyrolysis, and heating waste to a plasma.

5. Apparatus according to claim 1, where said magnetron's magnet is an electromagnet, and
where said electromagnet is connected to a power supply that energizes said electromagnet.

6. Apparatus according to claim 5, where, when it is desired to turn off the magnetron power supply, the electromagnet's power supply is turned off so that said magnetron will no longer emit microwave energy.

7. Apparatus according to claim 1, where the magnetron power supply is on the property of and operated by the high-voltage, public-utility that supplies the electric service required to power said magnetron power supply.

8. Apparatus according to claim 1, where said magnetron power supply is movable and transportable,
disconnecting the magnetron power supply circuit from both the utility service and ground,
loading said disconnected magnetron power supply onto a transport vehicle, transporting said power supply to a location equipped with a high voltage utility service,
connecting said magnetron power supply to said new location's high voltage utility service and to ground.

9. A variable-output, magnetron power supply which comprises:
a high-voltage, public-utility, electric service connected in series with a variable capacitor, a magnetron and ground,
where said magnetron power supply is located in the basement of a high rise residential or office building and is configured to dry and then burn up waste emanating from said residential or office building, and
where said high-voltage, public-utility, electric service is underground.
